(19) United States
(12) Patent Application Publication
(10) Pub. No.: US 2020/0075113 A1
(43) Pub. Date: Mar. 5, 2020

(54) SHIFT REGISTER UNIT, DRIVE METHOD, GATE DRIVE CIRCUIT AND DISPLAY DEVICE

(71) Applicants: Hefei Xinsheng Optoelectronics Technology Co., Ltd., Hefei (CN); BOE Technology Group Co., Ltd., Beijing (CN)

(72) Inventors: Can Yuan, Beijing (CN); Yongqian Li, Beijing (CN); Zhidong Yuan, Beijing (CN)

(73) Assignees: Hefei Xinsheng Optoelectronics Technology Co., Ltd.; BOE Technology Group Co., Ltd.

(21) Appl. No.: 16/451,150

(22) Filed: Jun. 25, 2019

(30) Foreign Application Priority Data
Aug. 29, 2018 (CN) 201811007283.7

(51) Int. Cl. G11C 19/28; G09G 3/20

(52) U.S. Cl. CPC G11C 19/287; G09G 3/20; G09G 2310/08; G09G 2300/0809; G09G 2310/0286; G09G 2300/0426

(57) ABSTRACT

A shift register unit, a drive method, a gate drive circuit and a display device are provided, in the field of display technologies. A first input signal terminal connected to an input control circuit of the shift register unit is connected to a first output terminal of a shift register unit at a previous stage, and a second input signal terminal connected to the input control circuit is connected to a second output terminal of the shift register unit at the previous stage. A signal output by the first output terminal of the shift register unit at the previous stage is a first clock signal and a signal output by the second output terminal is a second clock signal. Therefore, the first control node of the shift register unit may be controlled by flexibly adjusting a timing sequence of the first clock signal and the second clock signal.

This application claims priority to Chinese Patent Application No.: 201811007283.7, filed on Aug. 29, 2018 and entitled “SHIFT REGISTER UNIT, DRIVE METHOD, GATE DRIVE CIRCUIT AND DISPLAY DEVICE”, the entire contents of which are incorporated herein by reference.

### TECHNICAL FIELD

The present disclosure relates to the field of display technologies, and in particular to a shift register unit, a drive method, a gate drive circuit and a display device.

### BACKGROUND

With development of the display technologies, in order to guarantee the normal operation of a display device, a pixel circuit may include a switch transistor, a drive transistor and a detection sub-circuit. The detection sub-circuit may be configured to detect a voltage of a light-emitting device, and compensate for a threshold voltage Vth of the drive transistor based on the detected voltage. Correspondingly, two gate lines need to be arranged to control operation of the switch transistor and the detection sub-circuit, respectively.

### SUMMARY

The present disclosure provides a shift register unit, a drive method, a gate drive circuit and a display device.

In an aspect, there is provide a shift register unit, comprising: an input control circuit and an output circuit; wherein the input control circuit is connected to a first input signal terminal, a second input signal terminal and a first control node respectively, and the input control circuit is configured to adjust a potential of the first control node in response to a first input signal output by the first input signal terminal or a second input signal output by the second input signal terminal; and the output circuit is connected to the first control node, a first clock signal terminal, a second clock signal terminal, a first output terminal and a second output terminal respectively, and the output circuit is configured to output a first clock signal from the first clock signal terminal to the first output terminal and output a second clock signal from the second clock signal terminal to the second output terminal in response to the potential of the first control node; wherein the first input signal terminal is connected to a first output terminal of a shift register unit at a previous stage, and the second input signal terminal is connected to a second output terminal of the shift register unit at the previous stage.

Optionally, the input control circuit comprises: a first input control sub-circuit and a second input control sub-circuit; wherein the first input control sub-circuit is connected to the first input signal terminal and the first control node respectively, and the first input control sub-circuit is configured to output the first input signal to the first control node in response to the first input signal; and the second input control sub-circuit is connected to the second input signal terminal and the first control node respectively, and the second input control sub-circuit is configured to output the second input signal to the first control node in response to the second input signal.

Optionally, the first input control sub-circuit comprises: a first input control transistor; wherein a gate and a first electrode of the first input control transistor are both connected to the first input signal terminal, and a second electrode of the first input control transistor is connected to the first control node.

Optionally, the second input control sub-circuit comprises: a second input control transistor; wherein a gate and a first electrode of the second input control transistor are both connected to the second input signal terminal, and a second electrode of the second input control transistor is connected to the first control node.

Optionally, the output circuit comprises: a first output transistor and a second output transistor; wherein a gate of the first output transistor is connected to the first control node, a first electrode of the first output transistor is connected to the first clock signal terminal, and a second electrode of the first output transistor is connected to the first output terminal; and a gate of the second output transistor is connected to the first control node, a first electrode of the second output transistor is connected to the second clock signal terminal, and a second electrode of the second output transistor is connected to the second output terminal.

Optionally, the output circuit further comprises: a first capacitor and a second capacitor; wherein one terminal of the first capacitor is connected to the first control node, and the other terminal of the first capacitor is connected to the first output terminal; and one terminal of the second capacitor is connected to the first control node, and the other terminal of the second capacitor is connected to the second output terminal.

Optionally, the shift register unit further comprises: a pull-down circuit; wherein the pull-down circuit is connected to a second control node, a power source terminal the first output terminal and the second output terminal respectively, and the pull-down circuit is configured to output a power source signal from the power source terminal to the first output terminal and the second output terminal respectively in response to the potential of the second control node.

Optionally, the pull-down circuit comprises: a first pull-down transistor and a second pull-down transistor; wherein a gate of the first pull-down transistor is connected to the second control node, a first electrode of the first pull-down transistor is connected to the power source terminal, and a second electrode of the first pull-down transistor is connected to the first output terminal; and a gate of the second pull-down transistor is connected to the second control node, a first electrode of the second pull-down transistor is connected to the power source terminal, and a second electrode of the second pull-down transistor is connected to the second output terminal.

Optionally, the shift register unit further comprises: a detection scanning circuit; wherein the detection scanning circuit is connected to the first control node and the second control node respectively, and the detection scanning circuit is configured to control the potential of the first control node and the potential of the second control node.

Optionally, the detection scanning circuit is configured to control the second control node to be at a second potential when the first control node is at a first potential, and control the first control node to be at a second potential when the second control node is at a first potential.

Optionally, the shift register unit further comprises: a pull-down circuit and a detection scanning circuit; wherein the second input control sub-circuit comprises: a second input control transistor; the output circuit comprises: a first output transistor, a second output transistor, a first capacitor and a second capacitor; and the pull-down circuit comprises: a first pull-down transistor and a second pull-down transistor; wherein a gate and a first electrode of the second input control transistor are both connected to the second input signal terminal, and a second electrode of the second input control transistor is connected to the first control node; a gate of the first output transistor is connected to the first control node, a first electrode of the first output transistor is connected to the first clock signal terminal, and a second electrode of the first output transistor is connected to the first output terminal; a gate of the second output transistor is connected to the first control node, a first electrode of the second output transistor is connected to the second clock signal terminal, and a second electrode of the second output transistor is connected to the second output terminal; one terminal of the first capacitor is connected to the first control node, and the other terminal of the first capacitor is connected to the first output terminal; one terminal of the second capacitor is connected to the first control node, and the other terminal of the second capacitor is connected to the second output terminal; a gate of the first pull-down transistor is connected to the second control node, a first electrode of the first pull-down transistor is connected to the power source terminal, and a second electrode of the first pull-down transistor is connected to the first output terminal; a gate of the second pull-down transistor is connected to the second control node, a first electrode of the second pull-down transistor is connected to the power source terminal, and a econd electrode of the second pull-down transistor is connected to the second output terminal; and the detection scanning circuit is connected to the first control node and the second control node respectively, and the detection scanning circuit is configured to control the second control node to be at a second potential when the first control node is at a first potential, and control the first control node to be at a second potential when the second control node is at a first potential.

In another aspect, there is provided a drive method for a shift register unit, wherein the method is applied to drive the shift register unit in the above aspect. The method comprises: in an input stage, outputting a first input signal by the first input signal terminal, outputting a second input signal by the second input signal terminal, and adjusting by the input control circuit, the first control node to be at a first potential in response to an input signal at a first potential in the first input signal and the second input signal; and in an output stage in which the first control node is at the first potential, outputting, by the output circuit, a first clock signal from the first clock signal terminal to the first output terminal and outputting, by the output circuit, a second clock signal from the second clock signal terminal to the second output terminal in response to the first control node.

Optionally, the method further comprises: in a pull-down stage in which the second control node is at a first potential, outputting, by the pull-down circuit, a power source signal from a power source terminal to the first output terminal and the second output terminal respectively in response to the potential of the second control node, wherein the power source signal is at a second potential.

Optionally, the first clock signal and the second clock signal have the same timing sequence.

Optionally, one of the first clock signal and the second clock signal maintains at the second potential during the input stage and the output stage.

In yet another aspect, there is provided a gate drive circuit, comprising: at least two cascaded shift register units as described in the above aspect.

A first output terminal of the shift register unit at each stage is connected to a first input signal terminal of the shift register unit at a next stage, and a second output terminal of the shift register unit at each stage is connected to a second input signal terminal of the shift register unit at the next stage.

Optionally, at least two of the shift register units are connected to the same first clock signal terminal, and at least two of the shift register units are connected to the same second clock signal terminal.

Optionally, the shift register units at odd stages are connected to a same first clock signal terminal and are connected to a same second clock signal terminal; and the shift register units at even stages are connected to a same first clock signal terminal and are connected to a same second clock signal terminal; and the first clock signal terminal to which the shift register units at odd stages are connected is different from the first clock signal terminal and the second clock signal terminal to which the shift register units at even stages are connected, and the second clock signal terminal to which the shift register units at odd stages are connected is different from the second clock signal terminal to which the shift register units at even stages are connected.

In still yet another aspect, there is provided a display device, comprising the gate drive circuit as described in the above aspect.

### BRIEF DESCRIPTION OF THE DRAWINGS

In order to describe the technical solutions in the embodiments of the present more clearly, the following briefly introduces the accompanying drawings required for describing the embodiments. Apparently, the accompanying drawings in the following description show merely some embodiments of the present disclosure, and a person of ordinary skill in the art may also derive other drawings from these accompanying drawings without creative efforts.

FIG. 1 is a schematic diagram of a structure of a pixel circuit according to an embodiment of the present disclosure;

FIG. 2 is a schematic diagram of a structure of a shift register unit according to an embodiment of the present disclosure;

FIG. 3 is a schematic structural diagram of a structure of another shift register unit according to an embodiment of the present disclosure;

FIG. 4 is a schematic structural diagram of a structure of still another shift register unit according to an embodiment of the present disclosure;

FIG. 5 is a schematic structural diagram of a structure of yet still another shift register unit according to an embodiment of the present disclosure;

FIG. 6 is a schematic structural diagram of a structure of yet still another shift register unit according to an embodiment of the present disclosure;

FIG. 7 is a flowchart of a drive method for a shift register unit according to an embodiment of the present disclosure;

FIG. 8 is a timing sequence diagram of signal terminals of a gate drive circuit according to an embodiment of the present disclosure;

FIG. 9 is a timing sequence diagram of signal terminals of another gate drive circuit according to an embodiment of the present disclosure;

FIG. 10 is a timing sequence diagram of signal terminals of still another gate drive circuit according to an embodiment of the present disclosure; and

FIG. 11 is a schematic diagram of a structure of a gate drive circuit according to an embodiment of the present disclosure.

### DETAILED DESCRIPTION

The embodiments of the present disclosure will be described in further detail with reference to the accompanying drawings, to present the objects, technical solutions, and advantages of the present disclosure more clearly.

Transistors employed in all the embodiments of the present disclosure may be thin-film transistors or field-effect transistors or other devices having the same property. According to the function in the circuit, the transistors employed in the embodiments of the present disclosure are mainly switch transistors. Since the source and drain of the switch transistor employed herein are symmetric, the source and drain may be exchanged. In the embodiments of the present disclosure, the source is referred to as a first electrode, and the drain is referred to as a second electrode. Alternatively, the drain is referred to as a first electrode, and the source is referred to as a second electrode. According to morphology in the drawings, it is specified that a middle terminal of the transistor is the gate, a signal input terminal is the source, and a signal output terminal is the drain. In addition, the switch transistors employed in the embodiments of the present disclosure may include any one type of P-type switch transistors and N-type switch transistors. Here, the P-type switch transistor is turned on when the gate of the P-type switch transistor is at a low level, and is turned off when the gate of the P-type switch transistor is at a high level, and the N-type switch transistor is turned on when the gate of the N-type switch transistor is at a high level, and is turned off when the gate of the N-type switch transistor is at a low level.

In addition, in the embodiments of the present disclosure, signals all correspondingly have a first potential and a second potential. The first potential and the second potential only indicate that the signals have two different state quantities, instead of indicating that the first potential or the second potential herein in the whole text has a specific value. Additionally, in the embodiments of the present disclosure, the first potential may be an effective potential and the second potential may be an ineffective potential.

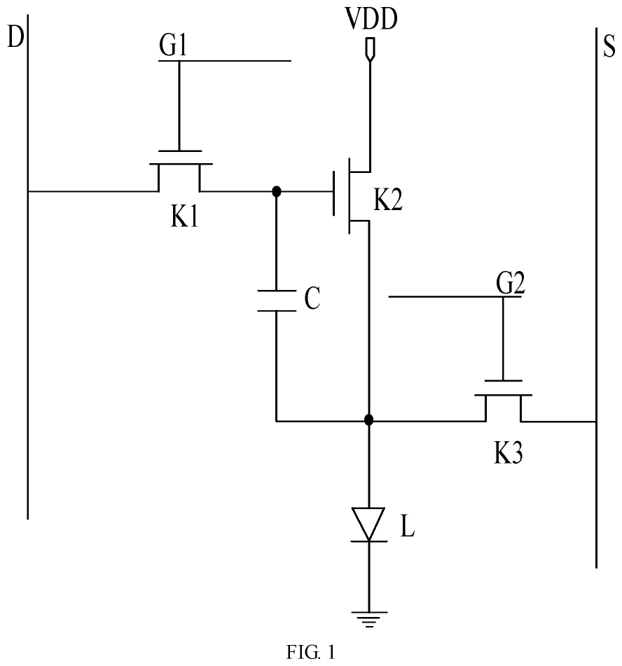

FIG. 1 is a schematic diagram of a structure of a pixel circuit according to an embodiment of the present disclosure. As illustrated in FIG. 1, the pixel circuit includes: a switch transistor K1, a drive transistor K2, a detection transistor K3 and a capacitor C.

The gate of the switch transistor K1 may be connected to a first gate line G1, the first electrode of the switch transistor K1 may be connected to a data signal line D, and the second electrode of the switch transistor K1 may be connected to the gate of the drive transistor K2. The switch transistor K1 may, under control of a gate signal provided by the first gate line G1, output a data signal provided by the data signal line D to the gate of the drive transistor K2, to control the drive transistor K2 to operate.

The first electrode of the drive transistor K2 may be connected to a direct-current power source terminal VDD, and the second electrode of the drive transistor K2 may be connected to an anode of a light-emitting unit L. The cathode of the light-emitting unit L may be grounded. The drive transistor K2 may, under control of the data signal and a direct-current power source signal provided by the direct-current power source terminal VDD, control the light-emitting unit L to emit light.

The gate of the detection transistor K3 may be connected to a second gate line G2, the first electrode of the detection transistor K3 may be connected to a detection signal line S, and the second electrode of the detection transistor K3 may be connected to the anode of the light-emitting unit L. The detection transistor K3 may, under control of a gate signal provided by the second gate line G2, output a detection signal to the anode of the light-emitting unit L, or acquire the signal parameter (for example, an output drive current) of the drive transistor K2 and send the acquired signal parameter to a compensation circuit, to enable the compensation circuit to compensate for the threshold voltage Vth of the drive transistor K2 based on the signal parameter.

One terminal of the capacitor C may be connected to the gate of the drive transistor K2, and the other terminal of the capacitor C may be connected to the anode of the light-emitting unit L. The capacitor C may, by means of a bootstrapping effect, pull up the gate voltage of the drive transistor K2, to ensure that the drive transistor K2 may be sufficiently turned on.

The related art provides a shift register unit. The shift register unit at each stage may include an input circuit, an output circuit and a pull-down circuit. Since the pixel circuit needs two gate lines, each shift register unit needs two output terminals connected to the two gate lines, respectively. Correspondingly, the output circuit may be connected to two clock signal terminals, a control node and two output terminals respectively. The output circuit may, under control of the control node, output clock signals provided by the two clock signal terminals to the two output terminal respectively. For example, the output circuit of the shift register unit at each stage may be connected to a control node, a first output terminal, a second output terminal, an output control terminal (that is, a CR signal terminal), a first clock signal terminal and a second clock signal terminal thereof respectively. The output circuit may, under control of the control node, output a first clock signal from the first clock signal terminal to the first output terminal and the output control terminal respectively, and output a second clock signal from the second clock signal terminal to the second output terminal. The input circuit of the shift register unit at each stage may be connected to the control node thereof, and the output control terminal of the shift register unit at a previous stage respectively. Therefore, the input circuit of the shift register unit at each stage may, under control of the output control terminal of the shift register unit at the previous stage, control the potential of the control node thereof.

However, in the related art, since the shift register unit at each stage may only, under control of the output control terminal of the shift register unit at the previous stage, control the potential of the control node thereof, the operating flexibility is low. The embodiments of the present disclosure provide a shift register unit, which can solve the problem that the operating flexibility of the shift register unit is low in the related art.

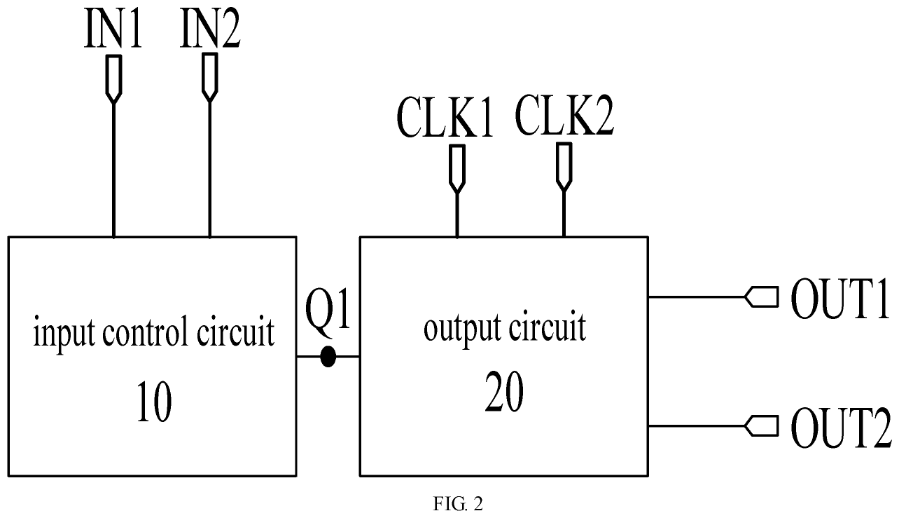

FIG. 2 is a schematic diagram of a structure of a shift register unit according to an embodiment of the present disclosure. As illustrated in FIG. 2, the shift register unit may include: an input control circuit 10 and an output circuit 20.

Referring to FIG. 2, the input control circuit 10 may be connected to a first input signal terminal IN1, a second input signal terminal IN2 and a first control node Q1 respectively, and the input control circuit 10 may control the potential of the first control node Q1 in response to a first input signal output by the first input signal terminal IN1 and a second input signal output by the second input signal terminal IN2.

Exemplarily, the input control circuit 10 may control the first control node Q1 to be at a first potential when the first input signal output by the first input signal terminal IN1 is at the first potential or the second input signal output by the second input signal terminal IN2 is at the first potential. For example, the input control circuit 10 may output the first input signal to the first control node Q1 when the first input signal output by the first input signal terminal IN is at the first potential. Alternatively, the input control circuit 10 may output the second input signal to the first control node Q1 when the second input signal output by the second input signal terminal IN is at the first potential.

The output circuit 20 may be connected to the first control node Q1, a first clock signal terminal CLK1, a second clock signal terminal CLK2, a first output terminal OUT1 and a second output terminal OUT2 respectively, and the output circuit 20 may output a first clock signal from the first clock signal terminal CLK1 to the first output terminal OUT1 and output a second clock signal from the second clock signal terminal CLK2 to the second output terminal OUT2 in response to the potential of the first control node Q1.

Exemplarily, the output circuit 20 may output the first clock signal from the first clock signal terminal CLK1 to the first output terminal OUT1 and output the second clock signal from the second clock signal terminal CLK2 to the second output terminal OUT2, when the first control node Q1 is at the first potential.

In the embodiments of the present disclosure, the first input signal terminal IN1 of the shift register unit at each stage may be connected to the first output terminal OUT1 (not shown in FIG. 1) of the shift register unit at a previous stage, and the second input signal terminal IN2 of the shift register unit at each stage may be connected to the second output terminal OUT2 (not shown in FIG. 2) of the shift register unit at the previous stage.

The input control circuit 10 of the shift register unit at each stage may, under control of the first output terminal OUT1 and the second output terminal OUT2 of the shift register unit at the previous stage, control the potential of the first control node Q1 thereof. The first output signal output by the first output terminal OUT1 of the shift register unit at the previous stage is the first clock signal provided by the first clock signal terminal CLK1 to which the shift register unit is connected, and the second output signal output by the second output terminal OUT2 of the shift register unit at the previous stage is the second clock signal provided by the second clock signal terminal CLK2 to which the shift register unit is connected. Thus, with respect to the shift register unit at each stage, the potential of the first control node Q1 of the shift register unit may be controlled by flexibly adjusting the timing sequence of the clock signals provided by the first clock signal terminal CLK1 and the second clock signal terminal CLK2 to which the shift register unit at the previous stage is connected, and thereby the operating flexibility of the shift register unit at each stage is effectively improved.

Furthermore, since the potential of the first control node Q1 is more flexibly controlled, the first gate signal provided by the shift register unit at each stage to the first gate line G1 to which the pixel circuit is connected and the second gate signal provided by the shift register to the second gate line G2 to which the pixel circuit is connected have a more diversified waveform, which may enable the pixel circuit to implement more functions. For example, the pixel circuit may implement such functions as threshold voltage compensation, short circuit detection and the like.

Exemplarily, referring to FIG. 1, when whether occurrence of a short circuit between the second gate line G2 to which the shift register unit at an n^{th} stage is connected and the detection signal line S is to be detected, the second output terminal OUT2 of the shift register unit at the n^{th} stage needs to output the second output signal at the first potential to the second gate line G2. That is, in this case, the second clock signal provided by the second clock signal terminal CLK2 to which the shift register unit at the n^{th} stage is connected should be at the first potential.

However, when the shift register unit in the related art is employed, the shift register unit at an (n−1)^{th} stage only can control the potential of the control node of the shift register unit at the n^{th} stage through an output control terminal, and the control signal output by the output control terminal is the first clock signal. Therefore, if the shift register unit in the related art is employed, the shift register unit at the (n−1)^{th} stage may only control the control node of the shift register unit at the n^{th} stage to be at the first potential when the shift register unit at the (n−1)^{th} stage outputs the first clock signal to the first output terminal and the output control terminal thereof and when the first clock signal is at the first potential. Furthermore, the output circuit of the shift register unit at the n^{th} stage may only, under control of the control node thereof, control the second output terminal thereof to output the second clock signal at the first potential, to achieve the function of short circuit detection. As known from the above analysis, in the process of the short circuit detection, even if the shift register unit at the (n−1)^{th} stage does not need to output the first clock signal at the first potential to the gate line to which the shift register unit is connected via the first output terminal, since the control node of the shift register unit at the n^{th} stage needs to be controlled to be at the first potential, the shift register unit at the (n−1)^{th} stage still needs to output the first clock signal at the first potential to the first output terminal. The operating flexibility is low when the shift register unit is operating.

According to the shift register unit provided in the embodiments of the present disclosure, in the process of the short circuit detection, if the shift register unit at the (n−1)^{th} stage does not need to output the first clock signal at the first potential via the first output terminal, the shift register unit at the (n−1)^{th} stage may be controlled to output the first clock signal to the first output terminal thereof and output the second clock signal to the second output terminal thereof, and the first clock signal may be controlled to be at the second potential, and the second clock signal may be controlled to be at the first potential. In this case, the shift register unit at the (n−1)^{th} stage control the first control node Q1 of the shift register unit at the n^{th} stage to be at the first potential through the second output signal (i.e., the second clock signal) output by the second output terminal OUT2 of shift register unit at the (n−1)^{th} stage. Further, the output circuit 20 of the shift register unit at the n^{th} stage may, under control of the first control node Q1 thereof, output the second output signal at the first potential, to achieve the function of short circuit detection. Here, N is the number of stages of the shift register units included in the gate drive circuit, and n is a positive integer not greater than N.

In summary, the embodiments of the present disclosure provide a shift register unit. The input control circuit of the shift register unit is connected to the first input signal terminal, the second input signal terminal and the first control node respectively. The first input signal terminal is connected to the first output terminal of the shift register unit at the previous stage, the second input signal terminal is connected to the second output terminal of the shift register unit at the previous stage. Therefore, the shift register unit may control the potential of the first control node thereof, under control of the first output signal output by the first output terminal of the shift register unit at the previous stage and the second output signal output by the second output terminal of the shift register unit at the previous stage. In addition, the first output signal output by the first output terminal of the shift register unit at the previous stage is the first clock signal output by the first clock signal terminal to which the shift register unit at the previous stage is connected, and the second output signal output by the second output terminal is the second clock signal output by the second clock signal terminal to which the shift register unit at the previous stage is connected. Therefore, the potential of the first control node of the shift register unit may be controlled by flexibly adjusting the timing sequence of the clock signals output by the first clock signal terminal and the second clock signal terminal. The operating flexibility of the shift register unit is high.

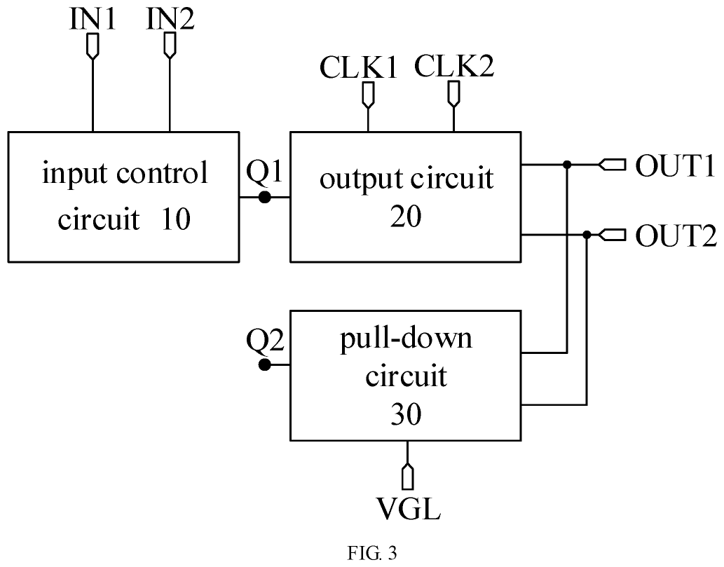

Optionally, as shown in FIG. 3, the shift register unit may further include a pull-down circuit 30. The pull-down circuit 30 may be connected to a second control node Q2, a power source terminal VGL, the first output terminal OUT1 and the second output terminal OUT2 respectively. The pull-down circuit 30 may output a power source signal from the power source terminal VGL to the first output terminal OUT1 and the second output terminal OUT2 respectively in response to the potential of the second control node Q2.

Exemplarily, the pull-down circuit 30 may output the power source signal from the power source terminal VGL to the first output terminal OUT1 and the second output terminal OUT2 respectively when the second control node Q2 is at the first potential. The power source signal may be at the second potential. That is, the pull-down circuit 30 may, under control of the second control node Q2, reset the first output terminal OUT1 and the second output terminal OUT2.

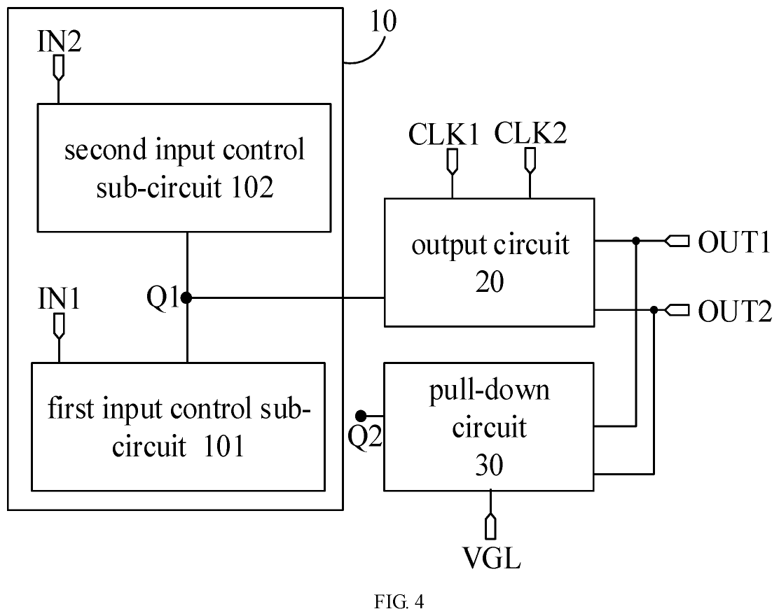

FIG. 4 is a schematic diagram of a structure of still another shift register unit according to an embodiment of the present disclosure. As an optional implementation, as shown in FIG. 4, the input control circuit 10 may include: a first input control sub-circuit 101 and a second input control sub-circuit 102.

Referring to FIG. 4, the first input control sub-circuit 101 may be connected to the first input signal terminal IN1 and the first control node Q1 respectively, and the first input control sub-circuit 101 may output the first input signal to the first control node Q1 in response to the first input signal.

Exemplarily, the first input control sub-circuit 101 may output the first input signal to the first control node Q1 when the first input signal is at the first potential, to control the first control node Q1 to be at the first potential.

The second input control sub-circuit 102 may be connected to the second input signal terminal IN2 and the first control node Q1 respectively, and the second input control sub-circuit 102 may output the second input signal to the first control node Q1 in response to the second input signal.

Exemplarily, the second input control sub-circuit 101 may output the second input signal to the first control node Q1 when the second input signal is at the first potential, to control the second control node Q2 to be at the first potential.

As an optional implementation, the first input control sub-circuit 101 may be connected to a direct-current power source terminal, the first input signal terminal IN1 and the first control node Q1 respectively. The direct-current power source terminal may provide a direct-current power source signal at a first potential. The first input control sub-circuit 101 may output a direct-current power source signal from the direct-current power source terminal to the first control node Q1 when the first input signal is at the first potential, to control the first control node Q1 to be at the first potential.

The second input control sub-circuit 102 may be connected to the direct-current power source terminal, the second input signal terminal IN2 and the first control node Q1 respectively. The second input control sub-circuit 102 may output the direct-current power source signal to the first control node Q1 when the second input signal is at the first potential, to control the second control node Q2 to be at the first potential.

In the embodiments of the present disclosure, two input control sub-circuits are arranged to be connected to the first input signal terminal IN1, the second input signal terminal IN2 and the first control node Q1 respectively, such that the shift register unit may, under control of the first input signal terminal IN1 and the second input signal terminal IN2, control the potential of the first control node Q1, thereby improving the operating flexibility of the shift register unit.

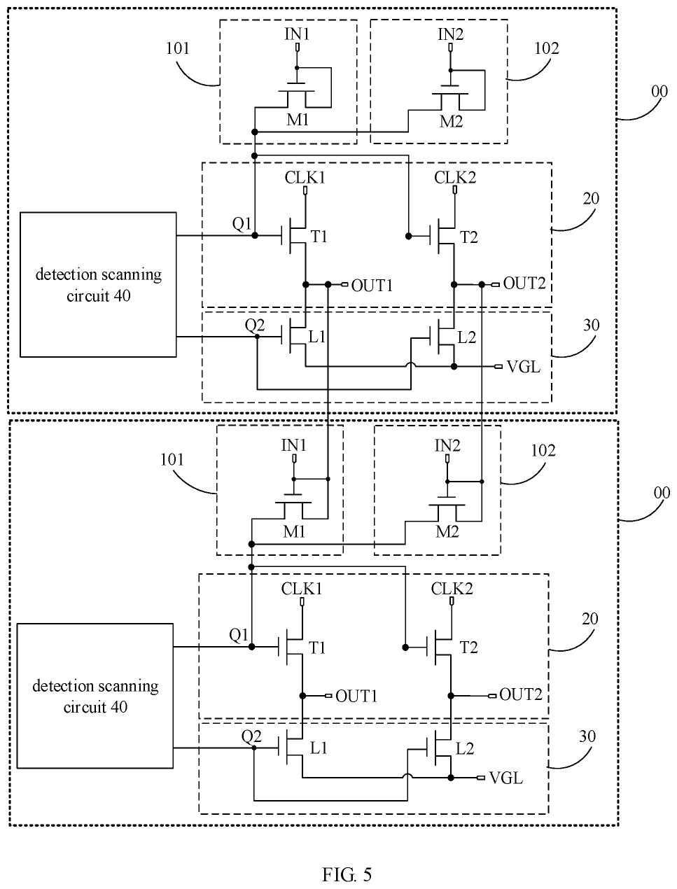

FIG. 5 is a schematic diagram of a structure of yet still another shift register unit 00 according to an embodiment of the present disclosure. As shown in FIG. 5, the first input control sub-circuit 101 may include a first input control transistor M1. The second input control sub-circuit 102 may include a second input control transistor M2.

Referring to FIG. 5, the gate and the first electrode of the first input control transistor M1 may be both connected to the first input signal terminal IN1, and the second electrode of the first input control transistor M1 may be connected to the first control node Q1. The first input control transistor M1 may be turned on when the first input signal is at the first potential, and output the first input signal to the first control node Q1.

The gate and the first electrode of the second input control transistor M2 may be both connected to the second input signal terminal IN2, and the second electrode of the second input control transistor M2 may be connected to the first control node Q1. The second input control transistor M2 may be turned on when the second input signal is at the first potential, and output the second input signal to the first control node Q1.

Two adjacent stages of shift register units are cascaded by arranging two input control transistors. Since the current flow of transistors is irreversible, current input to the first control node Q1 can be prevented from leakage, and the operating stability of the shift register unit is guaranteed.

Optionally, if each input control sub-circuit is further connected to the direct-current power source terminal, and is configured to output the direct-current power source signal to the first control node Q1, the gate of the first input control transistor M1 may be connected to the first input signal terminal IN1, the first electrode of the first input control transistor M1 may be connected to the direct-current power source terminal, and the second electrode of the first input control transistor M1 may be connected to the first control node Q1. The gate of the second input control transistor M2 may be connected to the second input signal terminal IN2, the first electrode of the second input control transistor M2 may be connected to the direct-current power source terminal, and the second electrode of the second input control transistor M2 may be connected to the first control node Q1.

Referring to FIG. 5, the output circuit 20 may include a first output transistor T1 and a second output transistor T2.

The gate of the first output transistor T1 may be connected to the first control node Q1, the first electrode of the first output transistor T1 may be connected to the first clock signal terminal CLK1, and the second electrode of the first output transistor T1 may be connected to the first output terminal OUT1.

The gate of the second output transistor T2 may be connected to the first control node Q1, the first electrode of the second output transistor T2 may be connected to the second clock signal terminal CLK2, and the second electrode of the second output transistor T2 may be connected to the second output terminal OUT2.

Here, each output transistor may be turned on when the first control node Q1 is at the first potential, and output the clock signal provided by the clock signal terminal to which the output transistor is connected to the output terminal to which the output transistor is connected.

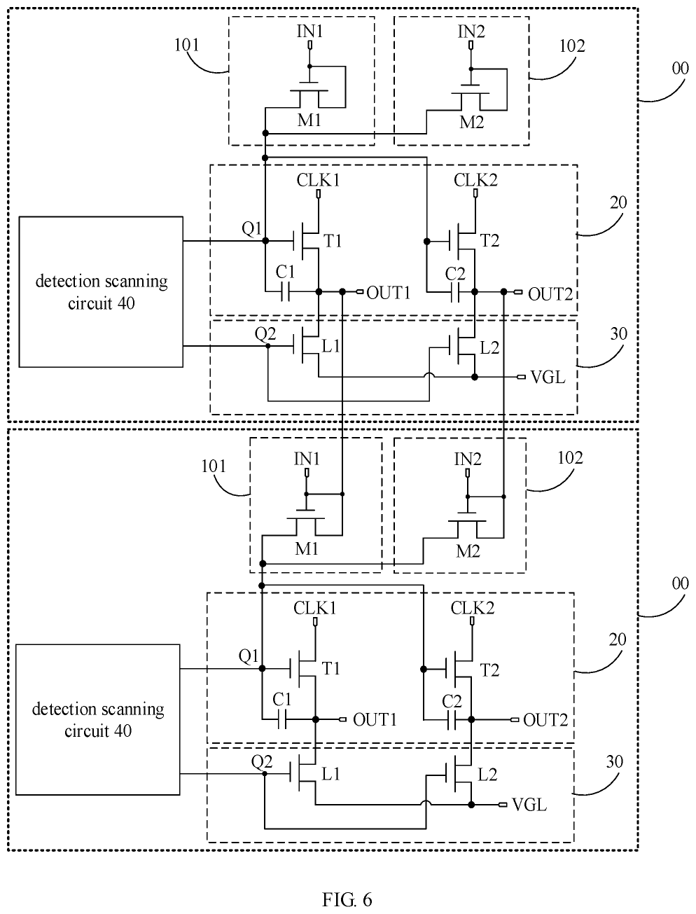

FIG. 6 is a schematic diagram of a structure of yet still another shift register unit 00 according to an embodiment of the present disclosure. As shown in FIG. 6, the output circuit 20 may further include a first capacitor C1 and a second capacitor C2.

One terminal of the first capacitor C1 may be connected to the first control node Q1, and the other terminal of the first capacitor C1 may be connected to the first output terminal OUT1.

One terminal of the second capacitor C2 may be connected to the first control node Q1, and the other terminal of the second capacitor C2 may be connected to the second output terminal OUT2.

By arranging these two capacitors C1 and C2, the potential of the first control node Q1 may be further pulled up under the bootstrapping effect of the two capacitors, which ensures that the two output transistors may be sufficiently turned on, and thereby ensures the reliability of the output signal of the output circuit 20.

Optionally, referring to FIG. 5 and FIG. 6, the pull-down circuit 30 may include a first pull-down transistor L1 and a second pull-down transistor L2.

The gate of the first pull-down transistor L1 may be connected to the second control node Q2, the first electrode of the first pull-down transistor L1 may be connected to the power source terminal VGL, and the second electrode of the first pull-down transistor L1 may be connected to the first output terminal OUT1.

The gate of the second pull-down transistor L2 may be connected to the second control node Q2, the first electrode of the second pull-down transistor L2 may be connected to the power source terminal VGL, and the second electrode of the second pull-down transistor L2 may be connected to the second output terminal OUT2.

Here, each pull-down transistor may be turned on when the second control node Q2 is at the first potential, and output the power source signal from the power source terminal VGL to the output terminal to which the pull-down transistor is connected, to reset the output terminal.

Referring to FIG. 5 and FIG. 6, the shift register unit 00 at each stage may further include a detection scanning circuit 40.

The detection scanning circuit 40 may be connected to the first control node Q1 and the second control node Q2 respectively, and the detection scanning circuit 40 may be configured to control the potential of the first control node Q1 and the potential of the second control node Q2.

Exemplarily, the detection scanning circuit 40 may control the second control node Q2 to be at the second potential when the first control node Q1 is at the first potential, and control the first control node Q1 to be at the second potential when the second control node Q2 is at the first potential.

Optionally, the detection scanning circuit 40 may include a reset sub-circuit and a pull-down control sub-circuit. The reset sub-circuit may be connected to a plurality of signal terminals and the first control node Q1 respectively, and the pull-down control sub-circuit may be connected to at least one signal terminal and the second control node Q2 respectively.

The reset sub-circuit may, under control of signals provided by the respective signal terminals, control the potential of the first control node Q1. For example, the reset sub-circuit may be connected to a reset signal terminal and the power source terminal VGL respectively, and the reset sub-circuit may provide the power source signal from the power source terminal VGL to the first control node Q1 when a reset signal provided by the reset signal terminal is at the first potential, to reset the first control node Q1.

Exemplarily, the reset sub-circuit may include a reset transistor. The gate of the reset transistor may be connected to the reset signal terminal, the first electrode of the reset transistor may be connected to the power source terminal VGL, and the second electrode of the reset transistor may be connected to the first control node Q1.

The pull-down control sub-circuit may, under control of the signals provided by the respective signal terminals, control the potential of the second control node Q2. For example, the pull-down control sub-circuit may be connected to the first control node Q1, the second control node Q2 and the power source terminal VGL respectively. The pull-down control sub-circuit may provide the power source signal from the power source terminal VGL to the second control node Q2 when the first control node Q1 is at the first potential, and provide the power source signal from the power source terminal VGL to the first control node Q1 when the second control node Q2 is at the first potential.

Exemplarily, the pull-down control sub-circuit may include two pull-down control transistors. The gate of one pull-down control transistor may be connected to the first control node Q1, the first electrode thereof may be connected to the power source terminal VGL, and the second electrode thereof may be connected to the second control node Q2. The gate of the other pull-down control transistor may be connected to the second control node Q2, the first electrode thereof may be connected to the power source terminal VGL, and the second electrode thereof may be connected to the first control node Q1.

Here, the first control node Q1 may be referred to as a pull-up node, and the second control node Q2 may be referred to as a pull-down node.

In the embodiments of the present disclosure, each of the reset sub-circuit and the pull-down control sub-circuit may include a plurality of transistors. The amount of transistors included and connection relationships therebetween are not limited in the embodiments of the present disclosure.

It should be noted that the above embodiments are all described by taking an example in which the transistors are all N-type transistors, and the first potential is a high potential relative to the second potential. Certainly, the transistors may also employ P-type transistors. When the transistors are P-type transistors, the first potential may be a low potential relative to the second potential.

In summary, this embodiments of the present disclosure provide a shift register unit. The input control circuit of the shift register unit is connected to the first input signal terminal, the second input signal terminal and the first control node respectively. The first input signal terminal is connected to the first output terminal of the shift register unit at the previous stage, the second input signal terminal is connected to the second output terminal of the shift register unit at the previous stage. Therefore, the shift register unit may control the potential of the first control node thereof, under control of the first output signal output by the first output terminal of the shift register unit at the previous stage and the second output signal output by the second output terminal of the shift register unit at the previous stage. In addition, the first output signal output by the first output terminal of the shift register unit at the previous stage is the first clock signal output by the first clock signal terminal to which the shift register unit at the previous stage is connected, and the second output signal output by the second output terminal is the second clock signal output by the second clock signal terminal to which the shift register unit at the previous stage is connected. Therefore, the potential of the first control node of the shift register unit may be controlled by flexibly adjusting the timing sequence of the clock signals output by the first clock signal terminal and the second clock signal terminal to which the shift register unit at the previous stage is connected. The operating flexibility of the shift register unit is high.

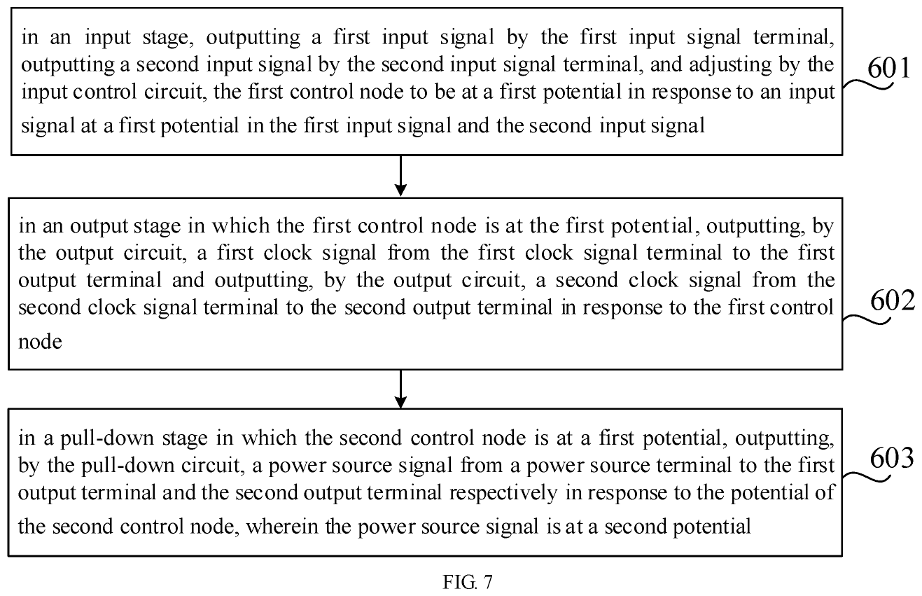

FIG. 7 is a flowchart of a drive method for a shift register unit according to an embodiment of the present disclosure. The drive method may be applied to drive the shift register unit as shown in any one of FIG. 2 to FIG. 6. As shown in FIG. 7, the method includes the following steps.

In step 601, in an input stage, the first input signal terminal outputs a first input signal, the second input signal terminal outputs a second input signal, and the input control circuit adjusts the first control node to be at a first potential in response to an input signal at a first potential in the first input signal and the second input signal.

In the embodiments of the present disclosure, in the input stage, the input control circuit 10 may output the first input signal to the first control node Q1 when the first input signal is at the first potential, or may output the second input signal to the first control node Q1 when the second input signal is at the first potential.

In the embodiments of the present disclosure, the first input signal terminal IN1 of the shift register unit at each stage may be connected to the first output terminal OUT1 of the shift register unit at a previous stage, and the second input signal terminal IN2 of the shift register unit at each stage may be connected to the second output terminal OUT2 of the shift register unit at the previous stage.

The input control circuit 10 of the shift register unit at each stage may control the potential of the first control node Q1 thereof, under control of the first output terminal OUT1 and the second output terminal OUT2 of the shift register unit at the previous stage. In addition, the first output signal output by the first output terminal OUT1 of the shift register unit at the previous stage is the first clock signal provided by the first clock signal terminal CLK1 to which the shift register unit at the previous stage is connected, and the second output signal output by the second output terminal OUT2 is the second clock signal provided by the second clock signal terminal CLK2 to which the shift register unit at the previous stage is connected. Therefore, the potential of the first control node Q1 of the shift register unit at each stage may be controlled by adjusting the timing sequence of the clock signals provided by the first clock signal terminal CLK1 and the second clock signal terminal CLK2 to which the shift register unit at a previous stage is connected, thereby effective improving the operating flexibility of the shift register unit at each stage.

In step 602, in an output stage, the first control node is at the first potential, and the output circuit outputs a first clock signal from a first clock signal terminal to the first output terminal and outputs a second clock signal from the second clock signal terminal to the second output terminal in response to the first control node.

In the embodiments of the present disclosure, in the output stage, the first control node Q1 is at the first potential, and the output circuit 20 may, under control of the first control node Q1, output the first clock signal from the first clock signal terminal CLK1 to the first output terminal OUT1, and output the second clock signal from the second clock signal terminal CLK2 to the second output terminal OUT2.

In summary, the embodiment of the present disclosure provides a drive method for a shift register unit. The input control circuit of the shift register unit may, under control of the first output signal output by the first output terminal and the second output signal output by the second output terminal of the shift register unit at the previous stage, control the potential of the first control node. In addition, the first output signal output by the first output terminal of the shift register unit at the previous stage is the first clock signal output by the first clock signal terminal to which the shift register unit at the previous stage is connected, and the second output signal output by the second output terminal is the second clock signal output by the second clock signal terminal to which the shift register unit at the previous stage is connected. Therefore, the potential of the first control node of the shift register unit may be controlled by flexibly adjusting the timing sequence of the clock signals output by the first clock signal terminal and the second clock signal terminal to which the shift register unit at the previous stage is connected. The operating flexibility of the shift register unit is high.

Optionally, still referring to FIG. 7, the method may further include the following steps.

In step 603, during a pull-down stage, the second control node is at the first potential, and the pull-down circuit outputs a power source signal from the power source terminal to the first output terminal and the second output terminal respectively in response to the potential of the second control node. The power source signal is at the second potential.

In the embodiments of the present disclosure, during the pull-down stage, the second control node Q2 is at the first potential, and the pull-down circuit 30 may, under control of the second control node Q2, output the power source signal at the second potential to the first output terminal OUT1 and the second output terminal OUT2 respectively, thereby resetting the first output terminal OUT1 and the second output terminal OUT2.

In an optional implementation of the embodiments of the present disclosure, the first clock signal terminals CLK1 to which the shift register units at varied stages are connected may be the same clock signal terminal, and the second clock signal terminals CLK2 to which the shift register units at varied stages are connected may also be the same clock signal terminal. That is, the shift register units at varied stages may be connected to the same first clock signal terminal, and may be connected to the same second clock signal terminal.

In another optional implementation manner of the embodiments of the present disclosure, the first clock signal terminals CLK1 to which the shift register units at odd stages are connected are the same clock signal terminal, and the second clock signal terminals CLK2 to which the shift register units at the odd stages are connected are the same clock signal terminal. The first clock signal terminals CLK1 to which the shift register units at even stages are connected are the same clock signal terminal, and the second clock signal terminals CLK2 to which the shift register units at the even stages are connected are the same clock signal terminal. In addition, the first clock signal terminal CLK1 to which the shift register units at the odd stages are connected is different from the first clock signal terminal CLK1 to which the shift register units at the even stages are connected. Also, the second clock signal terminal CLK2 to which the shift register units at odd stages are connected is different from the second clock signal terminal CLK2 to which the shift register units at even stages are connected.

For example, the first clock signal terminals CLK1 to which the shift register units at the odd stages are connected are all a clock signal terminal CK1, and the second clock signal terminals CLK2 to which the shift register units at the odd stages are connected are all a clock signal terminal CK2. The first clock signal terminals CLK1 to which the shift register units at the even stages are connected are all a clock signal terminal CK3, and the second clock signal terminals CLK2 to which the shift register units at the even stages are connected are all a clock signal terminal CK4.

The principle of driving the shift register unit according to the embodiments of the present disclosure are described in detail by taking the shift register unit as shown in FIG. 6 as an example, and by taking an example in which the transistors in the shift register unit are N-type transistors, the first potential is a high potential relative to the second potential, the first clock signal terminal CLK1 to which the shift register units at odd stages are connected is the clock signal terminal CK1 and the second clock signal terminal CLK2 to which the shift register units at the odd stages are connected is the clock signal terminal CK2, the first clock signal terminal CLK1 to which the shift register units at even stages are connected is the clock signal terminal CK3, and the second clock signal terminal CLK2 to which the shift register units at the even stages are connected is the clock signal terminal CK4.

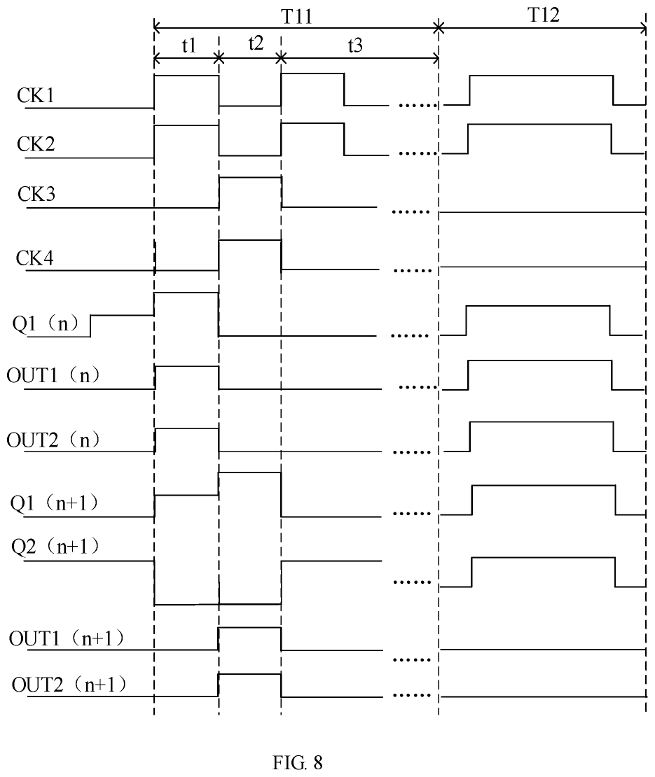

FIG. 8 is a timing sequence diagram of signals output by signal terminals in a gate drive circuit in a display stage T11 and a blank stage T12 according to an embodiment of the present disclosure.

The process of driving the shift register unit is described in detail by taking the shift register unit at the (n+1)^{th} (the (n+1)^{th} stage are an even stage) stage in the date drive circuit as an example, and by taking an example in which the first clock signal output by the first clock signal terminal CLK1 and the second clock signal output by the second clock signal terminal CLK2 of the shift register unit at each stage have the same timing sequence (that is, the clock signal terminal CK1 and the clock signal terminal CK2 have the same timing sequence, and the clock signal terminal CK3 and the clock signal terminal CK4 have the same timing sequence).

The first input signal terminal IN1 of the shift register unit at the (n+1)^{th} stage is connected to the first output terminal OUT1 of the shift register unit at the n^{th} stage, and the second input signal terminal IN2 of the shift register unit at the (n+1)^{th} stage is connected to the second output terminal OUT2 of the shift register unit at the n^{th} stage. Therefore, the timing sequence of the first input signal output by the first input signal terminal IN1 of the shift register unit at the (n+1)^{th} stage may be made reference to the timing sequence of OUT1(n) as illustrated in FIG. 8, and the timing sequence of the second input signal output by the second input signal terminal IN2 of the shift register unit at the (n+1)^{th} stage may be made reference to the timing sequence of OUT2(n) as illustrated in FIG. 8.

As shown in FIG. 8, the display stage T11 may include: an input stage t1, an output stage t2 and a pull-down stage t3.

Here, in the input stage t1, the clock signals output by the clock signal terminal CK1 and the clock signal terminal CK2 to which the shift register unit at the n^{th} stage is connected are both at the first potential, and the shift register unit at the (n−1)^{th} stage may control the first control node Q1(n) of the shift register unit at the n^{th} stage to be at the first potential. Therefore, in this case, the first output transistor T1 and the second output transistor T2 in the output circuit 20 of the shift register unit at the n^{th} stage are both turned on. The clock signal terminal CK1 may output the first output signal at the first potential to the first output terminal OUT1(n) via the first output transistor T1, and the clock signal terminal CK2 may output the second output signal at the first potential to the second output terminal OUT2(n) via the second output transistor T2.

Correspondingly, the first input signal output by the first input signal terminal IN1 and the second input signal output by the second input signal terminal IN2 of the shift register unit at the (n+1)^{th} stage are both at the first potential. The first input control transistor M1 and the second input control transistor M2 of the shift register unit at the (n+1)^{th} stage are both turned on, the first input signal terminal IN1 outputs the first input signal at the first potential to the first control node Q1(n+1) via the first input control transistor M1, and the second input signal terminal IN2 outputs the second input signal at the first potential to the first control node Q1(n+1) via the second input control transistor M2. Thus, the potential of the first control node Q1(n+1) is pulled up, thereby charging the first control node Q1(n+1).

At the output stage t2, the potential of the first output signal output by the first output terminal OUT1(n) and the potential of the second output signal output by the second output terminal OUT2(n) of the shift register unit at the n^{th} stage both hop to the second potential. Correspondingly, the potential of the first input signal output by the first input signal terminal IN1 and the potential of the second input signal output by the second input signal terminal IN2 of the shift register unit at the (n+1)^{th} stage both hop to the second potential. In addition, at the output stage t2, the clock signals output by the clock signal terminal CK3 and the clock signal terminal CK4 to which the shift register unit at the (n+1)^{th} stage is connected are both at the first potential.

In this case, the potential of the first control node Q1(n+1) of the shift register unit at the (n+1)^{th} stage is further pulled up under a coupling effect of the first capacitor C1 and the second capacitor C2, and the first output transistor T1 and the second output transistor T2 are sufficiently turned on under control of the first control node Q1(n+1). The clock signal terminal CK3 to which the shift register unit at the (n+1)^{th} stage is connected may output the clock signal at the first potential to the first output terminal OUT1(n+1) via the first output transistor T1. In addition, the clock signal terminal CK4 to which the shift register unit at the (n+1)^{th} stage is connected may output the clock signal at the first potential to the second output terminal OUT2(n+1) via the second output transistor T2.

In the pull-down stage t3, the second pull-down control node Q2(n+1) of the shift register unit at the (n+1)^{th} stage is at the first potential, and the first pull-down transistor L1 and the second pull-down transistor L2 are turned on. The power source terminal VGL of the shift register unit at the (n+1)^{th} stage outputs the power source signal at the second potential to the first output terminal OUT1(n+1) and the second output terminal OUT2(n+1) of the shift register unit at the (n+1)^{th} stage via the first pull-down transistor L1 and the second pull-down transistor L2, thereby implementing noise reduction for the first output terminal OUT1(n+1) and the second output terminal OUT2(n+1) of the shift register unit at the (n+1)^{th} stage.

In addition, as illustrated in FIG. 8, in the blank stage T2, if the switch transistors K1 and the detection transistors K3 in the n^{th} row of pixel circuits need to be controlled to be turned on, for example, in the circumstance where the threshold voltage of the drive transistor K2 needs to be detected, the first control node Q1(n) of the shift register unit at the n^{th} stage may be controlled to be at the first potential, and both the clock signals output by the clock signal terminal CK1 and the clock signal terminal CK2 to which the shift register unit at the n^{th} stage is connected may be controlled to be at the first potential. In this case, the first output transistor T1 and the second output transistor T2 of the shift register unit at the n^{th} stage are turned on. The clock signal terminal CK1 may output the clock signal at the first potential to the first output terminal OUT1(n) via the first output transistor T1. The clock signal terminal CK2 may output the clock signal at the first potential to the second output terminal OUT2(n) via the second output transistor T2. In this way, the shift register unit at the n^{th} stage may drive the switch transistors K1 and the detection transistors K3 in the n^{th} row of pixels circuit to be turned on.

In addition, as illustrated in FIG. 8, in the blank stage T2, if it is not necessary to control the switch transistors K1 and the detection transistors K3 in the (n+1)^{th} row of pixel circuits to be turned on, the clock signals output by the clock signal terminal CK3 and the clock signal terminal CK4 to which the shift register unit at the (n+1)^{th} stage is connected may be controlled to be at the second potential. In this case, even if the shift register unit at the n^{th} stage controls the first control node Q1(n+1) of the shift register unit at the (n+1)^{th} stage to be at the first potential, and the first output transistor T1 and the second output transistor T2 in the shift register unit at the (n+1)^{th} stage are turned on, the clock signal terminal CK3 still outputs a clock signal at the second potential to the first output terminal OUT1(n+1) via the first output transistor T1. The clock signal terminal CK4 also outputs a clock signal at the second potential to the second output terminal OUT2(n+1) via the second output transistor T2. In this way, the switch transistors K1 and the detection transistors K3 in the (n+1)^{th} row of pixel circuits both maintain to be turned off.

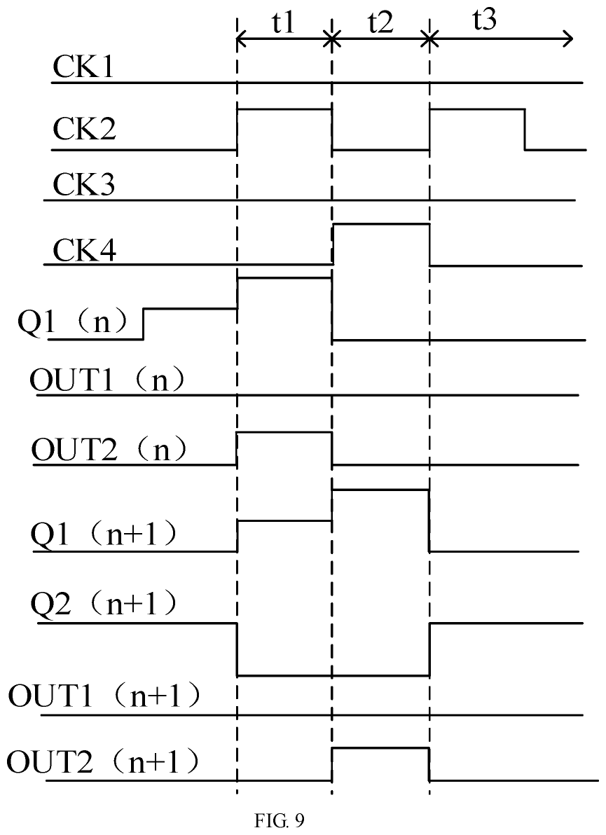

FIG. 9 is a timing sequence diagram of output signals from signal terminals of another gate drive circuit according to an embodiment of the present disclosure. The process of driving the shift register unit is described in detail by taking the shift register unit at the (n+1)^{th} stage in the gate drive circuit as an example, and by taking an example where the first clock signal (that is, the clock signal provided by the clock signal terminal CK1 and the clock signal provided by the clock signal terminal CK3) output by the first clock signal terminal CLK1 is always at the second potential.

In the input stage t1, the clock signal output by the clock signal terminal CK1 to which the shift register unit at the n^{th} stage is connected is at the second potential, the clock signal output by the clock signal terminal CK2 to which the shift register unit at the n^{th} stage is connected is at the first potential, and the shift register unit at the (n−1)^{th} stage controls the first control node Q1(n) of the shift register unit at the n^{th} stage to be at the first potential. Therefore, the first output transistor T1 and the second output transistor T2 in the output circuit 20 of the shift register unit at the n^{th} stage are both turned on, the clock signal terminal CK1 may output the first output signal at the second potential to the first output terminal OUT1(n) via the first output transistor T1, and the clock signal terminal CK2 may output the second output signal at the first potential to the second output terminal OUT2(n) via the second output transistor T2.

Correspondingly, the first input signal output by the first input signal terminal IN1 of the shift register unit at the (n+1)^{th} stage is at the second potential, and the second input signal output by the second input signal terminal IN2 of the shift register unit at the (n+1)^{th} stage is at the first potential. The first input control transistor M1 is turned off, and the second input control transistor M2 is turned on. The second input signal terminal IN2 of the shift register unit at the (n+1)^{th} stage outputs the second input signal at the first potential to the first control node Q1(n+1) via the second input control transistor M2. Thus, the potential of the first control node Q1(n+1) is pulled up, thereby charging the first control node Q1(n+1).

At the output stage t2, the potential of the second output signal output by the second output terminal OUT2(n) of the shift register unit at the n^{th} stage hops to the second potential. That is, the potential of the second input signal output by the second input signal terminal IN2 of the shift register unit at the (n+1)^{th} stage hops to the second potential. In addition, at the output stage t2, the clock signal output by the clock signal terminal CK3 to which the shift register unit at the (n+1)^{th} stage is connected is at the second potential, and the clock signal output by the clock signal terminal CK4 to which the shift register unit at the (n+1)^{th} stage is connected is at the first potential.

In this case, the potential of the first control node Q1(n+1) of the shift register unit at the (n+1)^{th} stage is further pulled up under a coupling effect of the second capacitor C2, and the first output transistor T1 and the second output transistor T2 are sufficiently turned on under control of the first control node Q1(n+1). The clock signal terminal CK3 to which the shift register unit at the (n+1)^{th} stage is connected outputs a clock signal at the second potential to the first output terminal OUT1(n+1) via the first output transistor T1, and the clock signal terminal CK4 to which the shift register unit at the (n+1)^{th} stage is connected outputs a clock signal at the first potential to the second output terminal OUT2(n+1) via the second output transistor T2.

The drive process in the pull-down stage t3 may be made reference to the drive process in the pull-down stage t3 described above, and will not repeated herein.

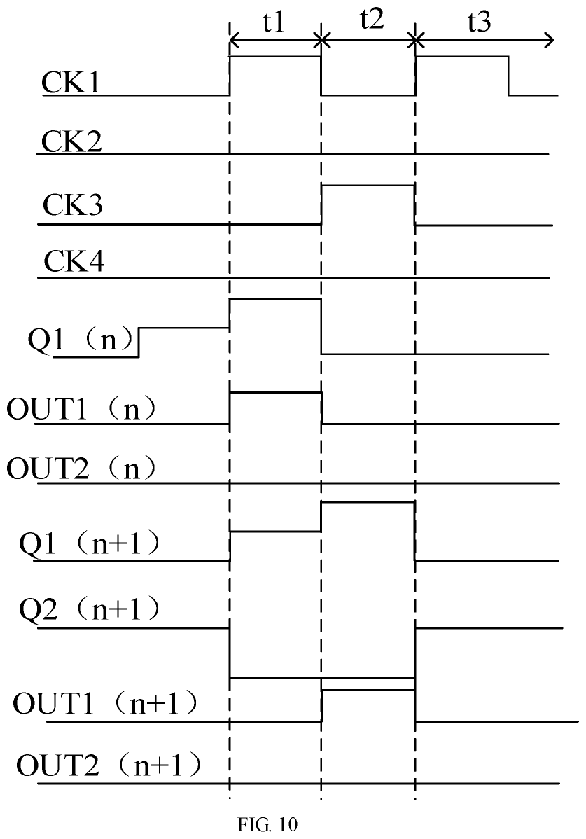

FIG. 10 is a timing sequence diagram of output signals from signal terminals of still another gate drive circuit according to an embodiment of the present disclosure. The process of driving the shift register unit is described in detail by taking the shift register unit at the (n+1)^{th} stage in the gate drive circuit as an example, and by taking an example where the second clock signal (that is, the clock signal provided by the clock signal terminal CK2 and the clock signal provided by the clock signal terminal CK4) output by the second clock signal terminal CLK2 is always at the second potential.

In the input stage t1, the clock signal output by the clock signal terminal CK1 to which the shift register unit at the n^{th} stage is connected is at the first potential, the clock signal output by the clock signal terminal CK2 to which the shift register unit at the n^{th} stage is connected is at the second potential, and the shift register unit at the (n−1)th stage controls the first control node Q1(n) of the shift register unit at the n^{th} stage to be at the first potential. Therefore, the first output transistor T1 and the second output transistor T2 in the output circuit 20 of the shift register unit at the n^{th} stage are both turned on, the clock signal terminal CK1 may output the first output signal at the first potential to the first output terminal OUT1(n) via the first output transistor T1, and the clock signal terminal CK2 may output the second output signal at the second potential to the second output terminal OUT2(n) via the second output transistor T2.

Correspondingly, the first input signal output by the first input signal terminal IN1 of the shift register unit at the (n+1)^{th} stage is at the first potential, and the second input signal output by the second input signal terminal IN2 of the shift register unit at the (n+1)^{th} stage is at the second potential. The first input control transistor M1 is turned on, and the second input control transistor M2 is turned off. The first input signal terminal IN1 of the shift register unit at the (n+1)^{th} stage outputs the first input signal at the first potential to the first control node Q1(n+1) via the first input control transistor M1, such that the potential of the first control node Q1(n+1) is pulled up, thereby charging the first control node Q1(n+1).

In the output stage t2, the potential of the first output signal output by the first output terminal OUT1(n) of the shift register unit at the n^{th} stage hops to the second potential. That is, the potential of the first input signal output by the first input signal terminal IN1 of the shift register unit at the (n+1)^{th} stage hops to the second potential. In addition, in the output stage t2, the clock signal output by the clock signal terminal CK3 to which the shift register unit at the (n+1)^{th} stage is connected is at the first potential, and the clock signal output by the clock signal terminal CK4 to which the shift register unit at the (n+1)^{th} stage is connected is at the second potential.

In this case, the potential of the first control node Q1(n+1) of the shift register unit at the (n+1)^{th} stage is further pulled up under a coupling effect of the first capacitor C1, and the first output transistor T1 and the second output transistor T2 are sufficiently turned on under control of the first control node Q1(n+1). The clock signal terminal CK3 to which the shift register unit at the (n+1)^{th} stage is connected outputs a clock signal at the first potential to the first output terminal OUT1(n+1) via the first output transistor T1, and the clock signal terminal CK4 to which the shift register unit at the (n+1)^{th} stage is connected outputs a clock signal at the second potential to the second output terminal OUT2(n+1) via the second output transistor T2.

The drive process in the pull-down stage t3 may be made reference to the drive process in the pull-down stage t3 described above, and will not repeated herein.

As known from the above analysis, the shift register unit at each stage according to the embodiments of the present disclosure may, under control of the first output signal output by the first output terminal OUT1 of the shift register unit at the previous stage and the second output signal output by the second output terminal OUT2 of the shift register unit at the previous stage, control the potential of the first control node Q1. In addition, the first output signal output by the first output terminal OUT1 of the shift register unit at the previous stage is the first clock signal output by the first clock signal terminal CLK1 to which the shift register unit at the previous stage is connected, and the second output signal output by the second output terminal OUT2 is the second clock signal output by the second clock signal terminal CLK2 to which the shift register at the previous stage is connected. Therefore, the potential of the first control node Q1 of the shift register unit at each stage may be controlled by adjusting the timing sequence of the clock signals output by the first clock signal terminal CLK1 and the second clock signal terminal CLK2 to which the shift register unit at a previous stage is connected, thereby effective improving the operating flexibility of the shift register unit.

For example, FIG. 8 is a timing sequence diagram of varied signal terminals during normal operation, of the shift register unit at the (n+1)^{th} stage when the first output signal (that is, the first clock signal) and the second output signal (that is, the second clock signal) from the shift register unit at the n^{th} stage are both at the first potential. FIG. 9 is a timing sequence diagram of varied signal terminals during normal operation, of the shift register unit at the (n+1)^{th} stage when the second output signal from the shift register unit at the at the n^{th} stage is at the first potential. FIG. 10 is a timing sequence diagram of varied signal terminals during normal operation, of the shift register unit at the (n+1)^{th} stage when the first output signal from the shift register unit at the at the n^{th} stage is at the first potential.

It should be noted that the above embodiments are described by taking an example in which the transistors are all N-type transistors, the first potential is a high potential relative to the second potential. Certainly, the transistors may also employ P-type transistors. When the transistors are P-type transistors, the first potential is a low potential relative to the second potential.

In summary, the embodiments of the present disclosure provide a drive method for a shift register unit. The input control circuit of the shift register unit may, under control of the first output signal output by the first output terminal and the second output signal output by the second output terminal of the shift register unit at the previous stage, control the potential of the first control node. In addition, the first output signal output by the first output terminal of the shift register unit at the previous stage is the first clock signal output by the first clock signal terminal to which the shift register unit at the previous stage is connected, and the second output signal output by the second output terminal is the second clock signal output by the second clock signal terminal to which the shift register unit at the previous stage is connected. Therefore, the potential of the first control node of the shift register unit may be controlled by flexibly adjusting the timing sequence of the clock signals output by the first clock signal terminal and the second clock signal terminal to which the shift register unit at the previous stage is connected. The operating flexibility of the shift register unit is high.

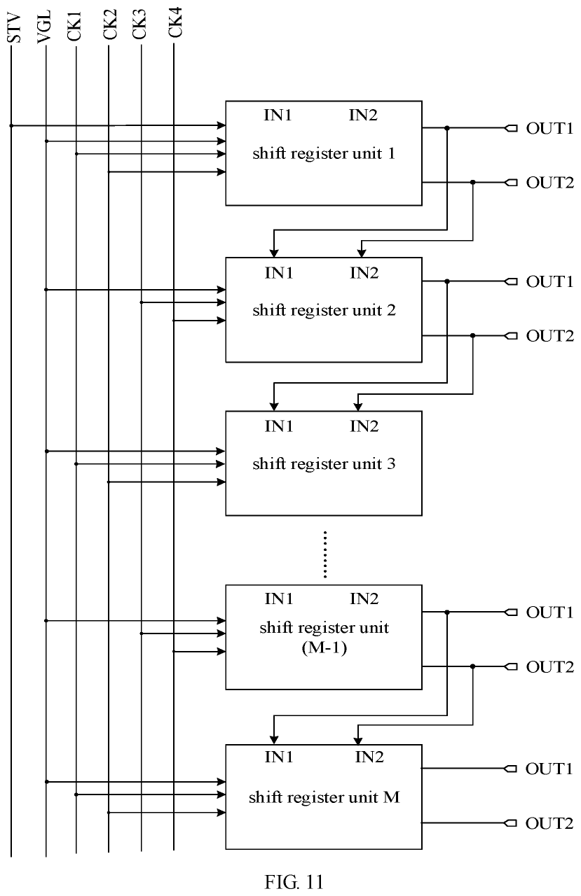

FIG. 11 is a schematic diagram of a structure of a gate drive circuit according to an embodiment of the present disclosure. As shown in FIG. 11, the gate drive circuit may include at least two cascaded shift register units. For example, the gate drive circuit shown in FIG. 11 may include M shift register units, wherein M is an integer greater than 1. Here, each shift register unit may be the shift register unit as shown in any one of FIG. 2 to FIG. 6.

Here, the first output terminal OUT1 of the shift register unit at each stage may be connected to the first input signal terminal IN1 of the shift register unit at a next stage, and the second output terminal OUT2 of the shift register unit at each stage may be connected to the second input signal terminal IN2 of the shift register unit at a next stage. In addition, the first output terminal OUT1 of the shift register unit at each stage may be further connected to one first gate line G1, and the second output terminal OUT2 of the shift register unit at each stage may be further connected to one second gate line G2. Here, as shown in FIG. 1, each first gate line G1 may be connected to the gate of the switch transistor KI in a row of pixel circuits, and each second gate line G2 may be connected to the gate of the detection transistor K3 in a row of pixel circuits.

In addition, an embodiment of the present disclosure further provides a display device. The display device may include the gate drive circuit as shown in FIG. 11. The display device may be: an electronic paper, an OLED panel, an AMOLED panel, a mobile phone, a tablet computer, a TV, a display, a laptop computer, a digital photo frame, a navigator or another product or part having a display function.

Persons of ordinary skill in the art would clearly understand that for the convenience and conciseness of description, the specific operation processes of the gate drive circuit, shift register unit and sub-circuits described above may be made reference to the relevant processes in the above-described method embodiments, and are not repeated herein.

The foregoing descriptions are merely exemplary embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A shift register unit, comprising: an input control circuit and an output circuit; wherein
the input control circuit is connected to a first input signal terminal, a second input signal terminal and a first control node respectively, and the input control circuit is configured to adjust a potential of the first control node in response to a first input signal output by the first input signal terminal or a second input signal output by the second input signal terminal; and
the output circuit is connected to the first control node, a first clock signal terminal, a second clock signal terminal, a first output terminal and a second output terminal respectively, and the output circuit is configured to output a first clock signal from the first clock signal terminal to the first output terminal and output a second clock signal from the second clock signal terminal to the second output terminal in response to the potential of the first control node;
wherein the first input signal terminal is connected to a first output terminal of a shift register unit at a previous stage, and the second input signal terminal is connected to a second output terminal of the shift register unit at the previous stage.

2. The shift register unit according to claim 1, wherein the input control circuit comprises: a first input control sub-circuit and a second input control sub-circuit; wherein
the first input control sub-circuit is connected to the first input signal terminal and the first control node respectively, and the first input control sub-circuit is configured to output the first input signal to the first control node in response to the first input signal; and
the second input control sub-circuit is connected to the second input signal terminal and the first control node respectively, and the second input control sub-circuit is configured to output the second input signal to the first control node in response to the second input signal.

3. The shift register unit according to claim 2, wherein the first input control sub-circuit comprises: a first input control transistor; wherein
a gate and a first electrode of the first input control transistor are both connected to the first input signal terminal, and a second electrode of the first input control transistor is connected to the first control node.

4. The shift register unit according to claim 2, wherein the second input control sub-circuit comprises: a second input control transistor; wherein
a gate and a first electrode of the second input control transistor are both connected to the second input signal terminal, and a second electrode of the second input control transistor is connected to the first control node.

5. The shift register unit according to claim 1, wherein the output circuit comprises: a first output transistor and a second output transistor; wherein
a gate of the first output transistor is connected to the first control node, a first electrode of the first output transistor is connected to the first clock signal terminal, and a second electrode of the first output transistor is connected to the first output terminal; and
a gate of the second output transistor is connected to the first control node, a first electrode of the second output transistor is connected to the second clock signal terminal, and a second electrode of the second output transistor is connected to the second output terminal.

6. The shift register unit according to claim 5, wherein the output circuit further comprises: a first capacitor and a second capacitor; wherein
one terminal of the first capacitor is connected to the first control node, and the other terminal of the first capacitor is connected to the first output terminal; and
one terminal of the second capacitor is connected to the first control node, and the other terminal of the second capacitor is connected to the second output terminal.

7. The shift register unit according to claim 1, further comprising: a pull-down circuit; wherein
the pull-down circuit is connected to a second control node, a power source terminal the first output terminal and the second output terminal respectively, and the pull-down circuit is configured to output a power source signal from the power source terminal to the first output terminal and the second output terminal respectively in response to a potential of the second control node.

8. The shift register unit according to claim 7, wherein the pull-down circuit comprises: a first pull-down transistor and a second pull-down transistor; wherein
a gate of the first pull-down transistor is connected to the second control node, a first electrode of the first pull-down transistor is connected to the power source terminal, and a second electrode of the first pull-down transistor is connected to the first output terminal; and
a gate of the second pull-down transistor is connected to the second control node, a first electrode of the second pull-down transistor is connected to the power source terminal, and a second electrode of the second pull-down transistor is connected to the second output terminal.

9. The shift register unit according to claim 7, further comprising: a detection scanning circuit; wherein
the detection scanning circuit is connected to the first control node and the second control node respectively, and the detection scanning circuit is configured to control the potential of the first control node and the potential of the second control node.

10. The shift register unit according to claim 9, wherein
the detection scanning circuit is configured to control the second control node to be at a second potential when the first control node is at a first potential, and control the first control node to be at a second potential when the second control node is at a first potential.

11. The shift register unit according to claim 3, further comprising: a pull-down circuit and a detection scanning circuit; wherein the second input control sub-circuit comprises: a second input control transistor; the output circuit comprises: a first output transistor, a second output transistor, a first capacitor and a second capacitor; and the pull-down circuit comprises: a first pull-down transistor and a second pull-down transistor; wherein
a gate and a first electrode of the second input control transistor are both connected to the second input signal terminal, and a second electrode of the second input control transistor is connected to the first control node;
a gate of the first output transistor is connected to the first control node, a first electrode of the first output transistor is connected to the first clock signal terminal, and a second electrode of the first output transistor is connected to the first output terminal;
a gate of the second output transistor is connected to the first control node, a first electrode of the second output transistor is connected to the second clock signal terminal, and a second electrode of the second output transistor is connected to the second output terminal;
one terminal of the first capacitor is connected to the first control node, and the other terminal of the first capacitor is connected to the first output terminal;
one terminal of the second capacitor is connected to the first control node, and the other terminal of the second capacitor is connected to the second output terminal;
a gate of the first pull-down transistor is connected to the second control node, a first electrode of the first pull-down transistor is connected to the power source terminal, and a second electrode of the first pull-down transistor is connected to the first output terminal;
a gate of the second pull-down transistor is connected to the second control node, a first electrode of the second pull-down transistor is connected to the power source terminal, and a second electrode of the second pull-down transistor is connected to the second output terminal; and
the detection scanning circuit is connected to the first control node and the second control node respectively, and the detection scanning circuit is configured to control the second control node to be at a second potential when the first control node is at a first potential, and control the first control node to be at a second potential when the second control node is at a first potential.

12. A drive method for a shift register unit, wherein the shift register unit comprises: an input control circuit and an output circuit; wherein the control circuit is connected to a first input signal terminal, a second input signal terminal and a first control node respectively; the output circuit is connected to the first control node, a first clock signal terminal, a second clock signal terminal, a first output terminal and a second output terminal respectively; and the method comprises:
in an input stage, outputting a first input signal by the first input signal terminal, outputting a second input signal by the second input signal terminal, and adjusting by the input control circuit, the first control node to be at a first potential in response to an input signal at a first potential in the first input signal and the second input signal; and
in an output stage, outputting, by the output circuit, a first clock signal from the first clock signal terminal to the first output terminal and outputting, by the output circuit, a second clock signal from the second clock signal terminal to the second output terminal in response to the first control node.

13. The method according to claim 12, further comprising:
in a pull-down stage in which the second control node is at a first potential, outputting, by the pull-down circuit, a power source signal from a power source terminal to the first output terminal and the second output terminal respectively in response to the potential of the second control node, wherein the power source signal is at a second potential.

14. The method according to claim 12, wherein
the first clock signal and the second clock signal have the same timing sequence.

15. The method according to claim 12, wherein
one of the first clock signal and the second clock signal maintains at the second potential during the input stage and the output stage.

16. A gate drive circuit, comprising: at least two cascaded shift register units; wherein the shift register unit comprises: an input control circuit and an output circuit; wherein
the input control circuit is connected to a first input signal terminal, a second input signal terminal and a first control node respectively, and the input control circuit is configured to adjust a potential of the first control node in response to a first input signal output by the first input signal terminal or a second input signal output by the second input signal terminal; and
the output circuit is connected to the first control node, a first clock signal terminal, a second clock signal terminal, a first output terminal and a second output terminal respectively, and the output circuit is configured to output a first clock signal from the first clock signal terminal to the first output terminal and output a second clock signal from the second clock signal terminal to the second output terminal in response to the potential of the first control node;
wherein a first output terminal of the shift register unit at each stage is connected to a first input signal terminal of the shift register unit at a next stage, and a second output terminal of the shift register unit at each stage is connected to a second input signal terminal of the shift register unit at the next stage.

17. The gate drive circuit according to claim 16, wherein the shift register unit further comprises: a pull-down circuit; wherein
the pull-down circuit is connected to a second control node, a power source terminal, the first output terminal and the second output terminal respectively, and the pull-down circuit is configured to output a power source signal from the power source terminal to the first output terminal and the second output terminal respectively in response to the second control node.

18. The gate drive circuit according to claim 16, wherein at least two of the shift register units are connected to the same first clock signal terminal, and at least two of the shift register units are connected to the same second clock signal terminal.

19. The gate drive circuit according to claim 16, wherein the shift register units at odd stages are connected to a same first clock signal terminal and are connected to a same second clock signal terminal; and the shift register units at even stages are connected to a same first clock signal terminal and are connected to a same second clock signal terminal; and the first clock signal terminal to which the shift register units at odd stages are connected is different from the first clock signal terminal and the second clock signal terminal to which the shift register units at even stages are connected, and the second clock signal terminal to which the shift register units at odd stages are connected is different from the second clock signal terminal to which the shift register units at even stages are connected.

20. A display device, comprising the gate drive circuit according to claim 16.
